(19) United States
(12) Patent Application Publication
(10) Pub. No.: US 2026/0033154 A1
(43) Pub. Date: Jan. 29, 2026

(54) DISPLAY PANEL AND PREPARATION METHOD THEREFOR

(71) Applicant: Hefei Visionox Technology Co., Ltd., Hefei (CN)

(72) Inventors: Xiaoxi SUN, Hefei (CN); Bo RAO, Hefei (CN); Yongqiang DU, Hefei (CN); Yuan YAO, Hefei (CN)

(73) Assignee: Hefei Visionox Technology Co., Ltd., Hefei (CN)

(21) Appl. No.: 19/271,714

(22) Filed: Jul. 16, 2025

(30) Foreign Application Priority Data
Jul. 25, 2024 (CN) 202411009111.9

(51) Int. Cl. H10K 59/122; H10K 59/12; H10K 59/35

(52) U.S. Cl. CPC H10K 59/122; H10K 59/1201; H10K 59/35

(57) ABSTRACT

The present application relates to a display panel, a preparation method therefor. The display panel includes a pixel defining layer, an isolation structure, and a plurality of light-emitting structures. The pixel defining layer has a plurality of pixel openings. An orthographic projection of a pixel opening on the substrate includes at least one first target edge and at least one first non-target edge. The isolation structure has a plurality of isolation openings, an orthographic projection of an isolation opening on the substrate includes at least one second target edge and at least one second non-target edge, a first distance is smaller than a second distance. Each light-emitting structure includes a light-emitting unit and a first electrode, an end of the first electrode corresponding to the second target edge being connected to the isolation structure.

### CROSS-REFERENCE TO RELATED APPLICATIONS

The present application claims priority to Chinese Patent Application No. 202411009111.9, filed on Jul. 25, 2024 and entitled “DISPLAY PANEL AND PREPARATION METHOD THEREFOR, DISPLAY DEVICE”, which is incorporated herein by reference in its entirety.

### FIELD

The present application relates to the field of display, and in particular to a display panel and a preparation method therefor.

### BACKGROUND

With the increasingly widespread application of display products, display technologies have been continuously evolving, and technologies that implement pixel patterning by means of photolithography processes have emerged. This technology revolutionizes traditional manufacturing processes and effectively increases pixel density (PPI) by means of exposure and development techniques.

Meanwhile, the lifespan of display products still needs to be improved.

### SUMMARY

In view of the above problems, a display panel and a preparation method therefor are provided, which can improve the product lifespan.

In a first aspect, the present application provides a display panel, comprising:
a substrate;
a pixel defining layer located on the substrate and having a plurality of pixel openings, an orthographic projection of a pixel opening on the substrate comprising at least one first target edge and at least one first non-target edge;
an isolation structure located on a side of the pixel defining layer away from the substrate and having a plurality of isolation openings in communication with the plurality of pixel openings, an orthographic projection of an isolation opening on the substrate comprising at least one second target edge and at least one second non-target edge, the at least one second target edge being arranged corresponding to the at least one first target edge, the at least one second non-target edge being arranged corresponding to the at least one first non-target edge, the orthographic projection of the pixel opening on the substrate being located within the orthographic projection of the isolation opening on the substrate, a distance between the first non-target edge and the second non-target edge being defined as a first distance, a distance between the first target edge and the second target edge being defined as a second distance, and the first distance being smaller than the second distance; and
a plurality of light-emitting structures located within the plurality of pixel openings and the plurality of isolation openings and comprising a plurality of light-emitting units and a plurality of first electrodes, within the isolation opening, an end of a first electrode corresponding to the second target edge being connected to the isolation structure.

In a second aspect, the present application provides another display panel, comprising:
a substrate;
a pixel defining layer located on the substrate and having a plurality of pixel openings, an orthographic projection of a pixel opening on the substrate comprising at least one first target edge;
an isolation structure located on a side of the pixel defining layer away from the substrate and having a plurality of isolation openings in communication with the plurality of pixel openings, an orthographic projection of an isolation opening on the substrate comprising at least one second target edge, the at least one second target edge being arranged corresponding to the at least one first target edge, the orthographic projection of the pixel opening on the substrate being located within orthographic projection of the isolation opening on the substrate, and a distance between the first target edge and the second target edge being defined as a second distance; and
a plurality of light-emitting structures located within the plurality of pixel openings and the plurality of isolation openings and comprising a plurality of light-emitting units and a plurality of first electrodes, within the isolation opening, an end of a first electrode corresponding to the second target edge being connected to the isolation structure, wherein the display panel comprises the plurality of light-emitting structures of different colors, in the plurality of light-emitting structures of different colors, the second distance corresponding to the light-emitting structure of at least one color being greater than the second distances corresponding to the light-emitting structures of other colors.

In a third aspect, the present application provides a method for preparing a display panel, the method comprising:
providing a substrate;
sequentially forming a pixel defining material layer and an isolation material layer on the substrate;
patterning the isolation material layer to form an isolation structure, wherein the isolation structure has a plurality of isolation openings, and an orthographic projection of an isolation opening on the substrate comprises at least one second target edge and at least one second non-target edge;
patterning the pixel defining material layer to form a patterned photoresist on the isolation structure and the pixel defining material layer;
etching the pixel defining material layer based on the patterned photoresist to form a pixel defining layer, wherein the pixel defining layer has a plurality of pixel openings, an orthographic projection of a pixel opening on the substrate is located within the orthographic projection of the isolation opening on the substrate, the orthographic projection of the pixel opening on the substrate comprises at least one first target edge and at least one first non-target edge, a distance between the first non-target edge and the second non-target edge is defined as a first distance, a distance between the first target edge and the second target edge is defined as a second distance, and the first distance is smaller than the second distance; and
forming a plurality of light-emitting structures within the plurality of pixel openings and the plurality of isolation openings, wherein the plurality of light-emitting structures comprise a plurality of light-emitting units and a plurality of first electrodes, an end of a first electrode corresponding to the second target edge being connected to the isolation structure.

In the display panel and the preparation method therefor described above, the orthographic projection of the pixel opening on the substrate comprises the at least one first target edge and the at least one first non-target edge, and the orthographic projection of the isolation opening on the substrate comprises the at least one second target edge and the at least one second non-target edge. Within the isolation opening, the end of the first electrode corresponding to the second target edge is connected to the isolation structure, and the distance between the second target edge and the first target edge is defined as a larger second distance. Therefore, in this case, etching damage to an upper surface of the pixel defining layer close to the first target edge can be effectively prevented or reduced. In this case, the upper surface of the pixel defining layer close to the first target edge is relatively flat, and a portion of the first electrode close to the second target edge will not be disconnected and can be effectively connected to the isolation structure, thereby improving the stability of the display panel. Moreover, the distance between the first non-target edge and the second non-target edge is defined as the first distance. The first distance is smaller than the second distance, and the area of the pixel opening can be effectively increased at the same pixel density, thereby improving the product lifespan.

### BRIEF DESCRIPTION OF THE DRAWINGS

In order to more clearly illustrate the embodiments of the present application or the prior art, a brief description of the accompanying drawings required for describing the embodiments or the prior art is provided below. The accompanying drawings in the following description show merely some embodiments of the present application.

FIG. 1 is a schematic partial top view of a display panel according to an embodiment of the present application;

FIG. 2 is a schematic partial cross-sectional view of the display panel according to an embodiment of the present application;

FIG. 3 is another schematic partial cross-sectional view of the display panel according to an embodiment of the present application;

FIG. 4 is a schematic top view of the display panel according to an embodiment of the present application;

FIG. 5 is a schematic partial top view of a display panel according to another embodiment of the present application;

FIG. 6 is a schematic flowchart of preparing a display panel according to an embodiment of the present application; and

FIG. 7 to FIG. 10 are schematic diagrams of structures during preparation of a display panel according to an embodiment of the present application.

### LIST OF REFERENCE SIGNS

10—photoresist, 100—substrate, 200—pixel defining layer, 200a—first target edge, 200b—first non-target edge, 2001—pixel opening, 300—isolation structure, 3001—isolation opening, 310—first isolation portion, 320—second isolation portion, 330—third isolation portion, 300a—second target edge, 300b—second non-target edge, 300c—first edge, 300d—second edge, 400—light-emitting structure, 410—light-emitting unit, 420—first electrode, 500—second electrode.

### DETAILED DESCRIPTION OF THE EMBODIMENTS

For ease of understanding the present application, the present application will be described more comprehensively below with reference to relevant accompanying drawings. Embodiments of the present application are given in the accompanying drawings. However, the present application may be implemented in many different forms and is not limited to the embodiments described herein. Rather, these embodiments are provided for a more thorough and comprehensive understanding of the content disclosed in the present application.

Unless otherwise defined, all terms used herein shall have the same meanings as commonly understood in the art to which the present application belongs. The terms used herein in the description of the present application are merely for the purpose of describing specific embodiments, and are not intended to limit the present application.

It should be noted that when an element is described as being “fixed to” another element, it may be directly fixed to another element or there may be an intermediate element therebetween. When one element is described as being “connected” to another element, it may be directly connected to another element or there may also be an intermediate element therebetween. The terms “vertical”, “horizontal”, “left”, “right” and similar expressions used herein are for illustrative purposes only.

In the drawings, the dimensions of layers and regions may be exaggerated for clarity of illustration. It should be understood that when a layer or element is described as being “on” another layer or the substrate, it may be directly on another layer or the substrate, or there may be an intermediate layer. In addition, It should be understood that when a layer is described as being “between” two layers, the layer may be the only layer between the two layers, or there may be one or more intermediate layers. In addition, like reference numerals always denote like elements.

In the following embodiments, when layers, regions, or elements are “connected”, it may be interpreted that the layers, regions, or elements are not only directly connected but also connected via other constituent elements disposed therebetween. For example, when layers, regions, elements, etc. are described as being connected or electrically connected, the layers, regions, elements, etc. may be directly connected or directly electrically connected, or may also be connected or electrically connected via another layer, region, or element disposed therebetween.

In the following description, although terms such as “first”, “second”, etc. may be used to describe various components, these components are not necessarily limited to the above terms. The above terms are used only to distinguish one component from another. It should also be understood that expressions used in the singular form include plural expressions unless the singular expression has clearly different meanings in the context.

When an expression such as “at least one of . . . ” is placed before a list of elements, it modifies the entire list of elements rather than individual elements in the list. The term “and/or” used herein includes any and all combinations of one or more of the associated listed items. As used in the application documents, the term “and/or” includes any and all combinations of one or more of the associated listed items. It should also be understood that the terms “include/comprise” or “have”, etc. specify the presence of stated features, integers, steps, operations, components, parts, or combinations thereof, but do not exclude the possibility of the presence or addition of one or more of other features, integers, steps, operations, components, parts, or combinations thereof.

Electronic or electrical devices and/or any other related device or component according to the implementations of the concepts of the present application described herein (e.g., a display device including a display panel and a display panel driver, wherein the display panel driver further includes a driving controller, a gate driver, a gamma reference voltage generator, a data driver, and an emission driver) can be implemented by using any suitable hardware, firmware (e.g., application-specific integrated circuits), software or a combination of software, firmware and hardware. For example, various components of the devices may be formed on an integrated circuit (IC) chip or formed on separate IC chips. In addition, various components of the devices may be implemented on a flexible printed circuit film, a tape carrier package (TCP), or a printed circuit board (PCB), or formed on a base substrate. In addition, various components of the devices may be processes or threads running on one or more processors in one or more computing devices to execute computer program instructions and to interact with other system components for performing various functions described herein. The computer program instructions are stored in a memory, which may be implemented in the computing device using standard storage devices (e.g., random access memory (RAM)). The computer program instructions may also be stored in other non-transitory computer-readable media (e.g., CD-ROM, flash drive, etc.). Further, it will be appreciated in the art that the functions of various computing devices may be combined or integrated into a single computing device, or the functions of a specific computing device may be distributed across one or more other computing devices, without departing from the spirit and scope of the exemplary embodiments of the concepts of the present application.

Although exemplary embodiments of a display panel and a display device including the display panel have been specifically described herein, various modifications and variations will be apparent in the art.

The related embodiments regarding the isolation structure are disclosed in patents CN 118251982 A, 202410864269.8, PCT/CN 2024/098407, PCT/CN 2024/102783, PCT/CN 2024/098217, PCT/CN 2024/100935, PCT/CN 2024/102785, PCT/CN 2024/099419, PCT/CN 2024/099072 and CN 116685174 A, the contents of which are incorporated herein by reference in their entirety. In one embodiment, with reference to FIG. 1 to FIG. 3, a display panel is provided. The display panel includes a substrate 100, a pixel defining layer 200, an isolation structure 300, and a plurality of light-emitting structures 400.

The substrate 100 may include a base substrate and a circuit layer (not shown) formed on the base substrate, etc. The base substrate may be a rigid base substrate or a flexible base substrate. The circuit layer may include a plurality of wiring layers and dielectric layers that isolate the wiring layers, etc., and a pixel circuit, etc. may be formed in the circuit layer.

The pixel defining layer 200 is located on the substrate 100. The pixel defining layer 200 has a plurality of pixel openings 2001. Specifically, with reference to FIG. 4, the display panel may include an active area AA and a non-active area. The plurality of pixel openings 2001 may be located in the active area AA.

A larger pixel opening 2001 provides a greater facing area between a cathode and an anode of a light-emitting device, resulting in a larger effective light-emitting area and a longer lifespan.

An orthographic projection of a pixel opening 2001 on the substrate includes at least one first target edge 200a and at least one first non-target edge 200b.

The pixel defining layer 200 may be of a stacked structure. The plurality of pixel openings 2001 may extend through the stacked structure. Of course, the pixel defining layer 200 may also be of a single-layer structure, which is not limited herein. The pixel defining layer 200 may be made of a material, including, but is not limited to, silicon oxide, silicon nitride, aluminum oxide, zirconium oxide, or hafnium oxide, etc.

The isolation structure 300 is located on the pixel defining layer 200, and specifically, the isolation structure 300 is located on a side of the pixel defining layer 200 away from the substrate 100. The isolation structure 300 has a barrier effect during evaporation of the light-emitting structure 400.

The isolation structure 300 is made of a conductive material, thereby enabling electrical connection.

The isolation structure 300 has a plurality of isolation openings 3001. The plurality of isolation openings 3001 are in communication with the plurality of pixel openings 2001, thereby allowing the formation of the plurality of light-emitting structures 400, etc.

An orthographic projection of an isolation opening 3001 on the substrate 100 includes at least one second target edge 300a and at least one second non-target edge 300b. The at least one second target edge 300a is arranged corresponding to the at least one first target edge 200a, and the at least one second non-target edge 300b is arranged corresponding to the at least one first non-target edge 200b. Specifically, the “corresponding” in “the at least one second target edge 300a is arranged corresponding to the at least one first target edge 200a” means that the at least one second target edge 300a and the at least one first target edge 200a are both located on the same side of an orthographic projection of the center of a light-emitting structure 400 on the substrate; and the “corresponding” in “the at least one second non-target edge 300b is arranged corresponding to the at least one first non-target edge 200b” means that the at least one second non-target edge 300b and the at least one first non-target edge 200b are both located on the same side of the orthographic projection of the center of the light-emitting structure 400 on the substrate.

One or more second target edges 300a may be provided, and one or more second non-target edges 300b may be provided, which are not limited herein.

The orthographic projection of the pixel opening 2001 on the substrate 100 is located within the orthographic projection of the isolation opening 3001 on the substrate 100. That is, the orthographic projection of the pixel opening 2001 on the substrate 100 is smaller than the orthographic projection of the isolation opening 3001 on the substrate 100.

Moreover, a distance between the first target edge 200a and the second target edge 300a is defined as a second distance MVP2. A distance between the first non-target edge 200b and the second non-target edge 300b is defined as a first distance MVP1. The first distance MVP1 is smaller than the second distance MVP2. That is, the second non-target edge 300b is closer to the pixel opening 2001 than the second target edge 300a.

The plurality of light-emitting structures 400 are located within the plurality of pixel openings 2001 and the plurality of isolation openings 3001. The plurality of light-emitting structures 400 includes a plurality of light-emitting units 410 and a plurality of first electrodes 420.

A light-emitting unit 410 may include a plurality of organic layers. A first electrode 420 may be a cathode or an anode. As an example, the first electrode 420 is a cathode, and the first electrodes 420 of the light-emitting structures 400 may be electrically connected to each other by connecting to the isolation structure 300.

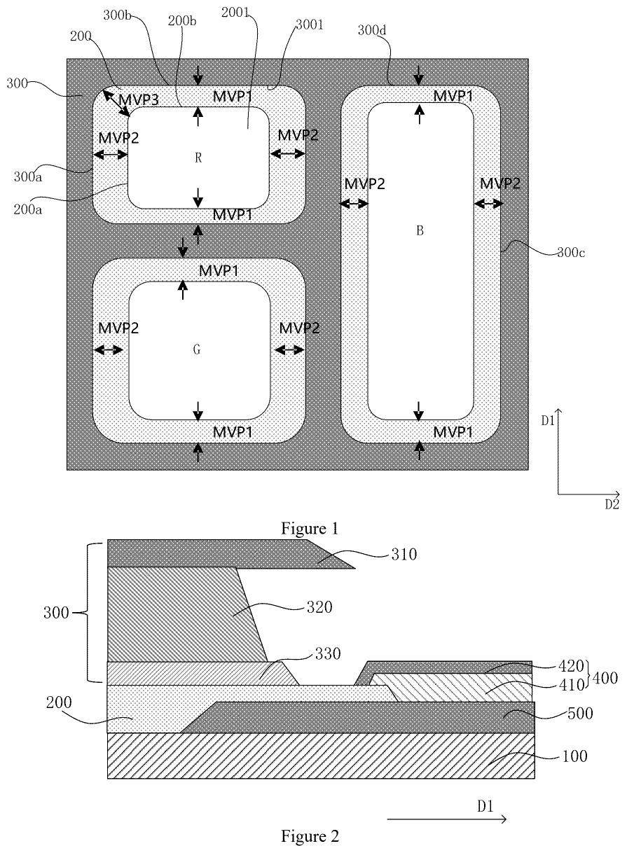

Within the isolation opening 3001, an end of the first electrode 420 corresponding to the second target edge 300a is connected to the isolation structure 300. Moreover, within the isolation opening 3001, an end of the first electrode 420 corresponding to the second non-target edge 300b may not be connected to the isolation structure 300 (as shown in FIG. 2), or may be connected to the isolation structure 300 (not shown), which is not limited herein. It should be understood that the “corresponding” in “an end of the first electrode 420 corresponding to the second target edge 300a” may means that an orthographic projection of the first electrode 420 on the substrate 100 and the second target edge 300a are located on the same side of the orthographic projection of the center of the light-emitting structure 400 on the substrate 100.

During preparation of the display panel, a pixel defining material layer and an isolation material layer may be first sequentially formed on the substrate 100. Then, the isolation material layer may be first patterned to form the isolation structure 300. Thereafter, the pixel defining material layer is patterned to form the pixel defining layer 200.

During the patterning of the pixel defining material layer, a photoresist may be first applied. In this case, due to the shielding effect of the isolation structure 300, a thickness of the photoresist on the pixel defining material layer becomes thinner as the photoresist approaches the orthographic projection of the isolation structure 300 on the substrate 100.

Then, the photoresist is exposed and developed to be patterned. The patterned photoresist has a plurality of photoresist openings that define the size and position, etc., of the plurality of pixel openings 2001.

Thereafter, the pixel defining material layer is etched based on the patterned photoresist to form the pixel defining layer 200 having the plurality of pixel openings 2001.

In this case, when the pixel opening 2001 formed by etching is close to the isolation structure 300, a corresponding photoresist opening also needs to be close to the isolation structure 300. As a result, the thickness of the photoresist around the photoresist opening may be thinner than that at other positions. Therefore, when the pixel defining material layer is etched based on the patterned photoresist, the thinner photoresist may be also etched away, thereby causing damage to the pixel defining material layer around the pixel opening 2001 and resulting in an uneven upper surface of the pixel defining layer 200 close to the pixel opening 2001. After the plurality of light-emitting structures 400 are subsequently formed, the unevenness of the pixel defining layer 200 may cause the first electrodes 420 to be prone to disconnection.

In this embodiment, the orthographic projection of the pixel opening 200 on the substrate includes the at least one first target edge 200a and the at least one first non-target edge 200b. The orthographic projection of the isolation opening 3001 on the substrate 100 includes the at least one second target edge 300a and the at least one second non-target edge 300b. Within the isolation opening 3001, the end of the first electrode 420 corresponding to the second target edge 300a is connected to the isolation structure 300, and the distance between the first target edge 200a and the second target edge 300a is defined as a larger second distance MVP2. Therefore, in this case, etching damage to the upper surface of the pixel defining layer 200 close to the first target edge 200a can be effectively prevented or reduced. That is, in this case, the upper surface of the pixel defining layer 200 close to the first target edge 200a is relatively flat, and a portion of the first electrode 420 close to the second target edge 300a will not be disconnected and can be effectively connected to the isolation structure 300.

Moreover, the distance between the first non-target edge 200b and the second non-target edge 300b is defined as the first distance MVP1. The first distance MVP1 is smaller than the second distance MVP2, and the area of the pixel opening 2001 can be effectively increased at the same pixel density, improving the aperture ratio, and thus improving the product lifespan.

In one embodiment, with reference to FIG. 1, two oppositely arranged edges of the orthographic projection of the isolation opening 3001 on the substrate 100 are the second target edges 300a. Specifically, the oppositely arranged edges may refer to edges of the orthographic projection of the isolation opening 3001 on the substrate 100 that are parallel to each other. In this embodiment, two second target edges 300a are provided, and the two second target edges 300a are oppositely arranged.

In this case, two oppositely arranged ends of the first electrode 420 may be effectively and reliably connected to the isolation structure 300, thereby reducing the overlap impedance and improving the overlap reliability.

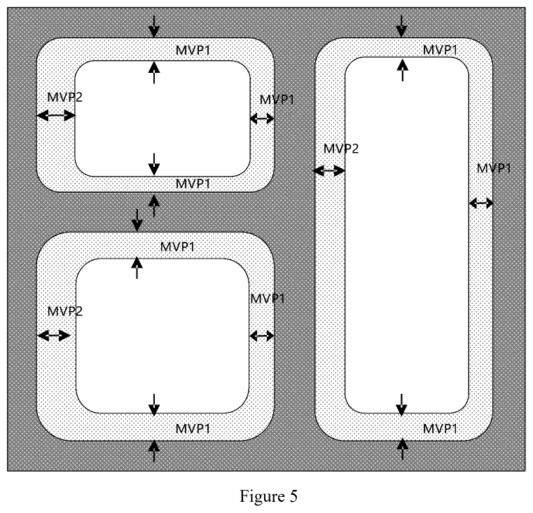

In one embodiment, with reference to FIG. 5, one of edges of the orthographic projection of the isolation opening 3001 on the substrate 100 is the second target edge 300a.

In this case, a larger second distance MVP2 may be provided on only one side of the pixel opening 2001, and a smaller first distance MVP1 may be provided on the remaining multiple sides of the pixel opening 2001, thereby facilitating further expansion of the area of the pixel opening 2001.

In one embodiment, with reference to FIG. 1, the display panel includes the plurality of light-emitting structures 400 of different colors. In the plurality of light-emitting structures 400 of different colors, the plurality of light-emitting units 410 are made of different materials, thereby emitting light of different colors.

The plurality of light-emitting structures 400 of different colors may include, for example, a plurality of red light-emitting structures R, a plurality of green light-emitting structures G, and a plurality of blue light-emitting structures B.

The first distances MVP1 corresponding to the light-emitting structures 400 of different colors are the same.

In this case, the first distance MVP1 corresponding to each of the plurality of light-emitting structures 400 of different colors may be set as a minimum threshold distance allowed between the orthographic projection of the pixel opening 2001 on the substrate 100 and the orthographic projection of the isolation opening 3001 on the substrate 100, and the area of the pixel opening 2001 corresponding to the light-emitting structure 400 of each color can be effectively increased. The minimum threshold distance may be set based on actual requirements.

As an example, the display panel further includes a plurality of second electrodes 500. The plurality of second electrodes 500 are located on the substrate 100. The pixel defining layer 200 is located on a side of a second electrode 500 away from the substrate 100. The pixel opening 2001 exposes at least part of the second electrode 500, and the light-emitting unit 410 of the light-emitting structure 400 can be connected to the second electrode 500.

The second electrode 500, the light-emitting unit 410, and the first electrode 420 may form a light-emitting device. It is possible to configure the second electrode 500 as an anode and the first electrode 420 as a cathode. It is also possible to configure the second electrode 500 as a cathode and the first electrode 420 as an anode.

Moreover, the first distance MVP1 may be set to be in a range of 0.6 μm to 2 μm. Specifically, the first distance may be 0.8 μm, 1.0 μm, 1.2 μm, 1.4 μm, 1.6 μm, 1.8 μm, or 2 μm. In one embodiment, the first distance may range from 1.2 μm to 2 μm.

In this case, on the one hand, the smaller first distance MVP1 allows the area of the pixel opening 2001 to be increased; on the other hand, since the first distance MVP1 is greater than zero, a sufficient distance may be maintained between the second electrode 500 and the isolation structure 300, thereby preventing a short circuit between the second electrode 500 and the first electrodes 420.

In one embodiment, with reference to FIG. 1, the display panel includes the plurality of light-emitting structures 400 of different colors. In the plurality of light-emitting structures 400 of different colors, the second distance MVP2 corresponding to the light-emitting structure 400 of at least one color is greater than the second distances MVP2 corresponding to the light-emitting structures 400 of other colors.

During preparation of the display panel, after the isolation structure 300 is formed, the plurality of light-emitting structures 400 of different colors may be sequentially formed. After the light-emitting structure 400 of one color is formed, the light-emitting structure 400 of another color is formed.

Moreover, during formation of the light-emitting structure 400 of each color, a light-emitting material layer may be first evaporated over an entire surface, followed by evaporation of a first electrode material layer over the entire surface. The evaporated light-emitting material layer and first electrode material layer are separated by the isolation structure 300 at the position of the isolation opening 3001. Then, an encapsulation material layer is deposited over the entire surface by a chemical vapor deposition process. Thereafter, a photoresist mask is formed by a photolithography process. Subsequently, the encapsulation material layer, the first electrode material layer, and the light-emitting material layer are etched based on the photoresist mask, to form a first encapsulation layer, a first electrode 420, and a light-emitting unit 410 within the isolation opening 3001 corresponding to a target color.

A dry etching method is typically used for the encapsulation material layer, and over-etching is usually required to completely etch the encapsulation material layer outside a region corresponding to the target color. Therefore, during etching of the encapsulation material layer for a post-deposited color, it is often necessary to etch into the first encapsulation layer already formed within the isolation opening 3001 for a pre-deposited color. In this case, when the second distance MVP2 corresponding to the pre-deposited color is not sufficiently large, the flatness of the upper surface of the pixel defining layer 200 corresponding to the second distance MVP2 may be insufficient. Consequently, although the light-emitting unit 410, the first electrode 420, and the first encapsulation layer for the pre-deposited color on the pixel defining layer 200 are continuous, there may still be uneven film thicknesses with thinner regions. During etching of the encapsulation material layer for the post-deposited color, the first encapsulation layer, the first electrode 420, and the light-emitting unit 410 within the isolation opening 3001 for the pre-deposited color may be etched through, and the pixel defining layer 200 beneath the light-emitting unit 410 may be damaged. This may cause metal to precipitate on the second electrode 500 beneath the pixel defining layer 200, leading to a short circuit between the second electrode and the first electrode 420, and thus leading to failure of a light-emitting device for the pre-deposited color.

Based on this, the second distance MVP2 corresponding to the light-emitting structure 400 of at least the first-prepared color may be set to be greater than the second distances MVP2 corresponding to the light-emitting structures 400 of other colors, thereby reducing the failure rate of light-emitting devices.

Specifically, as an example, the second distances MVP2 corresponding to the plurality of light-emitting structures 400 of different colors may be set to be completely different.

The earlier the preparation sequence of a color, the more times the first encapsulation layer already formed within the isolation opening 3001 therefor is etched. Therefore, it can be set that the color with an earlier preparation sequence corresponds to a larger second distance MVP2, and the color with a later preparation sequence corresponds to a smaller second distance MVP2, and the second distances MVP2 corresponding to the plurality of light-emitting structures 400 of different colors are completely different.

In this way, it is possible to prevent the failure of the pre-deposited color, and provide a larger pixel opening 2001 for the post-deposited color.

As another example, the plurality of light-emitting structures 400 of different colors include a plurality of first-color light-emitting structures 400, a plurality of second-color light-emitting structures 400, and a plurality of third-color light-emitting structures 400. The plurality of first-color light-emitting structures 400, the plurality of second-color light-emitting structures 400, and the plurality of third-color light-emitting structures 400 may be, for example, a plurality of red light-emitting structures R, a plurality of green light-emitting structures G, and a plurality of blue light-emitting structures B, respectively.

The second distance MVP2 corresponding to a first-color light-emitting structure 400 is greater than the second distance MVP2 corresponding to a second-color light-emitting structure 400. The second distance MVP2 corresponding to a third-color light-emitting structure 400 is greater than or equal to the second distance MVP2 corresponding to the second-color light-emitting structure 400.

As an example, the second distance MVP2 may be set to be in a range of 2 μm to 4 μm. Specifically, the second distance MVP2 may be 2 μm, 2.5 μm, 3 μm, 3.5 μm, 4 μm, etc.

As an example, the second distance MVP2 corresponding to the first-color light-emitting structure 400 may be set to be in a range of 2.5 μm to 4 μm, specifically, for example, 2.5 μm, 2.7 μm, 3 μm, 3.3 μm, 3.5 μm, 3.8 μm, or 4 μm. The second distance MVP2 corresponding to the second-color light-emitting structure 400 may be in a range of 2.5 μm to 3 μm, specifically, for example, 2.5 μm, 2.6 μm, 2.7 μm, 2.8 μm, 2.9 μm, or 3 μm. The second distance MVP2 corresponding to the third-color light-emitting structure 400 may be in a range of 2 μm to 2.5 μm, specifically, for example, 2 μm, 2.1 μm, 2.2 μm, 2.3 μm, 2.4 μm, or 2.5 μm.

The plurality of first-color light-emitting structures 400 may be prepared first. Then, the plurality of second-color light-emitting structures 400 or the plurality of third-color light-emitting structures 400 may be prepared, and finally, the light-emitting structures 400 of the remaining color are prepared.

In this case, a low failure rate of the first-color light-emitting structures 400 can be ensured. Moreover, the second distances MVP2 corresponding to the second-color light-emitting structures 400 and the third-color light-emitting structures 400 may both be set to be smaller, thereby allowing both to have larger pixel openings 2001.

In this embodiment, the second distance corresponding to the light-emitting structure of at least one color is set to be greater than those corresponding to the light-emitting structures of other colors. In this way, during preparation of the display panel, the light-emitting structure prepared earlier corresponds to a greater second distance, preventing damage to the light-emitting structure of the pre-deposited color during etching of the subsequently prepared light-emitting structure, and thus reducing the failure rate of light-emitting devices.

It should be noted that the above example, in which the second distances MVP2 corresponding to the plurality of light-emitting structures 400 of different colors are different based on different preparation sequences, illustrates that the second distances MVP2 corresponding to the plurality of light-emitting structures 400 of different colors may be different. However, the second distances MVP2 corresponding to the plurality of light-emitting structures 400 of different colors may also be set to be different without relying on the preparation sequence. During preparation of the display panel, the light-emitting structure 400 corresponding to a maximum second distance MVP2 is not limited to being the first prepared.

For example, in one embodiment, in the plurality of light-emitting structures 400 of different colors, the light-emitting structure 400 having a shortest lifespan corresponds to a largest second distance MVP2 (not shown).

In the plurality of light-emitting structures 400 of different colors, the plurality of light-emitting units 410 are made of different materials. The plurality of light-emitting structures 400 of different colors have different lifespans. The light-emitting structure 400 having the shortest lifespan typically has the largest pixel opening 2001 to extend the lifespan thereof. It should be understood that the lifespan of the plurality of light-emitting structures 400 of different colors may be determined based on the lifespan of each light-emitting structure 400 within the same area. The “light-emitting structure 400 having the shortest lifespan” refers to the light-emitting structure 400 having the shortest lifespan within the same area under the same test conditions.

Moreover, in this embodiment, the second distance MVP2 corresponding to the light-emitting structure 400 having the shortest lifespan is set to be the largest. As described above, the larger second distance MVP2 results in the flatter upper surface of the pixel defining layer 200 close to the pixel opening 2001, the smoother first electrode 420, and thus the lower overlap impedance between the first electrode 420 and the isolation structure 300, thereby increasing the lifespan of the light-emitting structure 400.

In one embodiment, the light-emitting structure 400 having a shorter lifespan corresponds to a larger second distance MVP2.

The plurality of light-emitting structures 400 of different colors include a plurality of first-color light-emitting structures, a plurality of second-color light-emitting structures, and a plurality of third-color light-emitting structures. The second distance corresponding to a first-color light-emitting structure is greater than the second distance corresponding to a second-color light-emitting structure. The second distance corresponding to the second-color light-emitting structure is greater than the second distance corresponding to a third-color light-emitting structure.

Additionally, the first-color light-emitting structure has a shorter lifespan than the second-color light-emitting structure, and the second-color light-emitting structure has a shorter lifespan than the third-color light-emitting structure.

For example, the plurality of light-emitting structures 400 of different colors include a plurality of red light-emitting structures R, a plurality of green light-emitting structures G, and a plurality of blue light-emitting structures B. The lifespan of a red light-emitting structure R is longer than that of a green light-emitting structure G, and the lifespan of the green light-emitting structure G is longer than that of a blue light-emitting structure B. Accordingly, the second distance MVP2 corresponding to the red light-emitting structure R may be set to be smaller than the second distance MVP2 corresponding to the green light-emitting structure G and smaller than the second distance MVP2 corresponding to the blue light-emitting structure B.

It will be appreciated that when the light-emitting structure 400 having the shortest lifespan corresponds to the largest second distance MVP2, during preparation of the display panel, the light-emitting structure 400 having the shortest lifespan may be, but is not limited to, prepared first.

When the light-emitting structure 400 prepared first during preparation of the display panel corresponds to the largest second distance MVP2, the light-emitting structure 400 may also, but is not limited to, be the light-emitting structure 400 having the shortest lifespan. For example, when the plurality of light-emitting structures 400 of different colors include the plurality of red light-emitting structures R, the plurality of green light-emitting structures G, and the plurality of blue light-emitting structures B, the first-prepared light-emitting structure 400 corresponding to the largest second distance MVP2 may be the red light-emitting structure R, the blue light-emitting structure B, or the green light-emitting structure G.

In one embodiment, with reference to FIG. 1, the display panel includes the plurality of light-emitting structures 400 of different colors. In the plurality of light-emitting structures 400 of different colors, the orthographic projection of the isolation opening 3001 corresponding to the light-emitting structure 400 having the shortest lifespan on the substrate 100 includes at least one first edge 300c and at least one second edge 300d.

For example, with reference to FIG. 1, the plurality of light-emitting structures 400 of different colors include the plurality of red light-emitting structures R, the plurality of green light-emitting structures G, and the plurality of blue light-emitting structures B. The light-emitting structure 400 having the shortest lifespan is the blue light-emitting structure B. The orthographic projection of the isolation opening 3001 corresponding to the blue light-emitting structure B on the substrate 100 includes at least one first edge 300c and at least one second edge 300d.

The at least one first edge 300c extends in a first direction D1 and the at least one second edge 300d extends in a second direction D2. The second direction D2 intersects the first direction D1. For example, the second direction D2 is perpendicular to the first direction D1.

The at least one first edge 300c has a greater length than the at least one second edge 300d. Therefore, the first direction D1 is a long-side direction. The second direction D2 is a short-side direction.

The second target edge 300a corresponding to the light-emitting structure 400 having the shortest lifespan is the first edge 300c.

The isolation opening 3001 corresponding to the light-emitting structure 400 having the shortest lifespan may have a plurality of first edges 300c. “A plurality of” means more than one. One of the first edges 300c may be used as the second target edge 300a, or more than one first edge 300c may be used as the second target edge 300a.

As an example, the orthographic projection of the isolation opening 3001 corresponding to the light-emitting structure 400 having the shortest lifespan on the substrate 100 may include two oppositely arranged first edges 300c. In this case, the two first edges 300c may be used as the second target edges 300a. Alternatively, the second target edge 300a may also be one of the first edges 300c.

For the light-emitting structure 400 having the shortest lifespan, the end of the first electrode 420 corresponding to the second target edge 300a (first edge 300c) is connected to the isolation structure 300. Specifically, the first electrode 420 may be connected to the isolation structure 300 in the second direction D2.

Since the first edge 300c is an edge having a larger length, the overlap area between the first electrode 420 of the light-emitting structure 400 having the shortest lifespan and the isolation structure 300 can be effectively increased, and the overlap impedance therebetween can be reduced. Therefore, the lifespan of the light-emitting structure 400 having the shortest lifespan can be effectively improved.

In one embodiment, the second target edges 300a corresponding to the other light-emitting structures 400 are parallel to the first edge 300c.

In this case, the first electrodes 420 of the plurality of light-emitting structures 400 of different colors are all connected to the isolation structure 300 in the same direction (second direction D2). During evaporation of the first electrodes 420 of the plurality of light-emitting structures 400 of different colors, the substrate 100 may be moved in the second direction D2, and within the plurality of isolation openings 3001 corresponding to the plurality of light-emitting structures 400 of different colors, the first electrodes 420 are all connected to the isolation structure 300 in the second direction D2.

In one embodiment, the second target edges 300a corresponding to the light-emitting structures 400 of different colors are all located on the same side of the light-emitting structures 400.

In this case, the first electrodes 420 of the plurality of light-emitting structures 400 of different colors are all connected to the isolation structure 300 on the same side (positive-direction side of the second direction D2 and/or negative-direction side of the second direction D2) in the same direction (second direction D2). During evaporation of the first electrodes 420 of the plurality of light-emitting structures 400 of different colors, the substrate 100 may be moved in the second direction D2. Additionally, the first electrodes 420 may be evaporated at the same evaporation angle.

In one embodiment, with reference to FIG. 1, the isolation opening 3001 includes at least one second straight edge and at least one second curved edge. The second target edge 300a is the second straight edge.

The isolation opening 3001 may have a plurality of second straight edges. One of the second straight edges may be used as the second target edge 300a, or more than one second straight edge may be used as the second target edge 300a.

During evaporation of the first electrodes 420, the substrate 100 is generally moved in a linear direction. When the second target edge 300a is a second straight edge perpendicular to the moving direction, the first electrode 420 may have a large overlap area with the isolation structure 300 at each position thereof in the direction perpendicular to the moving direction of the substrate 100.

In one embodiment, the second non-target edge 300b is also a second straight edge, and the second curved edge is located between the second non-target edge 300b and the second target edge 300a, or between two adjacent second non-target edges 300b.

In one embodiment, the orthographic projection of the pixel opening 200 on the substrate 100 includes at least one first straight edge and at least one first curved edge. The at least one first straight edge is arranged corresponding to the at least one second straight edge, and the at least one first curved edge is arranged corresponding to the at least one second curved edge. Additionally, a distance between the first curved edge and the second curved edge is defined as a third distance MVP3. The third distance is variable, and is greater on a side close to the first target edge 200a than on a side close to the first non-target edge 200b. Specifically, the “corresponding” in “the at least one first straight edge is arranged corresponding to the at least one second straight edge” means that the at least one first straight edge and the at least one second straight edge are both located on the same side of the orthographic projection of the center of the light-emitting structure 400 on the substrate 100; and the “correspondence” in “the at least one first curved edge is arranged corresponding to the at least one second curved edge” means that the at least one first curved edge and the at least one second curved edge are both located on the same side of the orthographic projection of the center of the light-emitting structure 400 on the substrate 100.

As an example, the isolation opening 3001 may be shaped like a rectangle. Moreover, corners of the rectangle-like isolation opening 3001 may be rounded, and the isolation opening 3001 has four second straight edges and four second curved edges.

The four second straight edges may include two first edges 300c extending in the first direction D1 and two second edges 300d extending in the second direction D2. In this case, the two first edges 300c may be used as the second target edges 300a, and the two second edges 300d may be used as the second non-target edges 300b. When the first electrodes 420 are evaporated, the substrate 100 may be moved in the second direction D2. The distance between the first edge 300c and the first target edge 200a is defined as the second distance MVP2. The distance between the second edge 300d and the first non-target edge 200b is defined as the first distance MVP1. The third distance MVP3 between the second curved edge between the first edge 300c and the second edge 300d and the corresponding first curved edge presents a transition trend without a fixed value. Additionally, the third distance MVP3 has a greater value on the side close to the first target edge 200a than on the side close to the first non-target edge 200b.

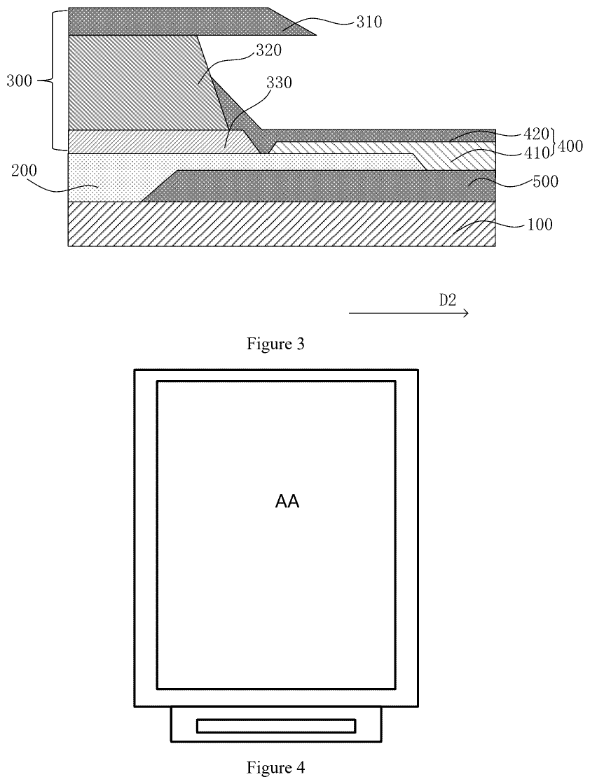

In one embodiment, with reference to FIG. 2 and FIG. 3, the isolation structure 300 may include a first isolation portion 310 and a second isolation portion 320. The first isolation portion 310 is located on a side of the second isolation portion 320 away from the substrate 100.

An orthographic projection of the second isolation portion 320 on the substrate 100 is located within an orthographic projection of the first isolation portion 310 on the substrate 100. Therefore, the first isolation portion 310 may have an eave portion extending from the second isolation portion 320.

In this case, the orthographic projection of the isolation opening 3001 on the substrate 100 is an orthographic projection of an opening of the first isolation portion 310 on the substrate 100.

In one embodiment, the second isolation portion 320 may be made of a conductive material. The first electrode 420 may overlap with a sidewall of the second isolation portion 320.

As an example, the isolation structure 300 further includes a third isolation portion 330. The third isolation portion 330 is located between the pixel defining layer 200 and the second isolation portion 320, and the orthographic projection of the second isolation portion 320 on the substrate 100 is located within an orthographic projection of the third isolation portion 330 on the substrate 100.

The third isolation portion 330 may be used for increasing the adhesion between the second isolation portion 320 and the pixel defining layer 200.

In one embodiment, the third isolation portion 330 may be made of a conductive material. In this case, the first electrode 420 may also overlap with a sidewall and/or a top surface of the third isolation portion 330.

In one embodiment, the display panel may further include a second encapsulation layer (not shown) and a third encapsulation layer (not shown). The second encapsulation layer may be an organic layer and may completely cover the first encapsulation layer and the isolation structure, and a surface of the second encapsulation layer away from the substrate may be a relatively flat surface. The third encapsulation layer may be an inorganic layer and is located on a side of the second encapsulation layer away from the substrate.

As an example, the display panel may further include at least one of a cover plate, a touch layer, and a polarizer on a side of the third encapsulation layer away from the substrate.

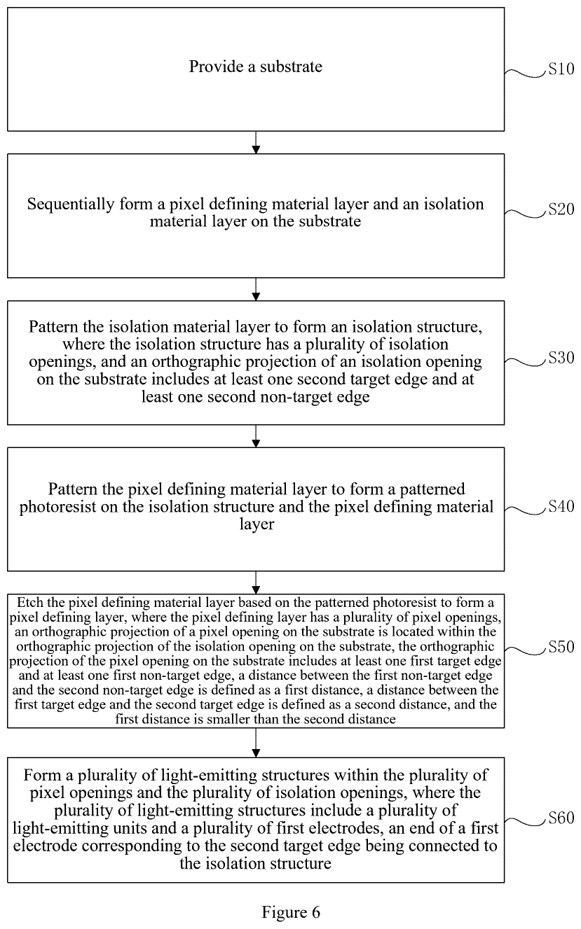

In one embodiment, with reference to FIG. 6, a method for preparing a display panel is further provided. The method specifically includes the following steps.

At step S10, with reference to FIG. 7, a substrate 100 is provided.

The substrate 100 may include a base substrate and a circuit layer (not shown) formed on the base substrate, etc. The base substrate may be a rigid base substrate or a flexible base substrate. The circuit layer may include a plurality of wiring layers and dielectric layers that isolate the wiring layers, etc., and a pixel circuit, etc. may be formed in the circuit layer.

At step S20, with continued reference to FIG. 7, a pixel defining material layer 2001 and an isolation material layer 3101 are sequentially formed on the substrate 100.

The pixel defining material layer 2001 may be of a stacked structure. Of course, the pixel defining material layer 2001 may also be of a single-layer structure, which is not limited herein. The pixel defining material layer 2001 may be made of a material, including, but is not limited to, silicon oxide, silicon nitride, aluminum oxide, zirconium oxide, or hafnium oxide, etc.

The isolation material layer 3101 may be of a stacked structure. For example, the isolation material layer 3101 includes a third isolation material layer 3301, a second isolation material layer 3201 and a first isolation material layer 3101 that are sequentially formed on the pixel defining material layer 2001.

At step S30, with reference to FIG. 8 and FIG. 1, the isolation material layer 3101 is patterned to form an isolation structure 300, where the isolation structure 300 has a plurality of isolation openings 3001, and an orthographic projection of an isolation opening 3001 on the substrate 100 includes at least one second target edge 300a and at least one second non-target edge 300b.

The isolation material layer 3101 may be patterned and etched by processes such as photolithography and wet etching to form the isolation structure 300 having the plurality of isolation openings 3001.

When the isolation material layer 3101 includes the third isolation material layer 3301, the second isolation material layer 3201 and the first isolation material layer 3101 that are sequentially formed on the pixel defining material layer 2001, during patterning and wet etching, the third isolation material layer 3301, the second isolation material layer 3201 and the first isolation material layer 3101 are etched at different rates by an etching solution, and a third isolation portion 330, a second isolation portion 320 and a first isolation portion 310 having different orthographic projection areas may be formed on the substrate 100.

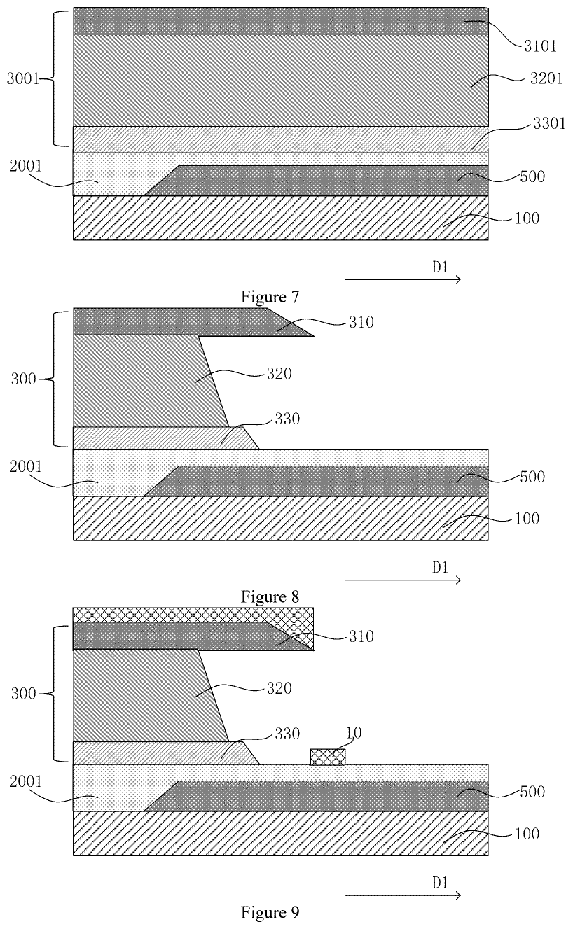

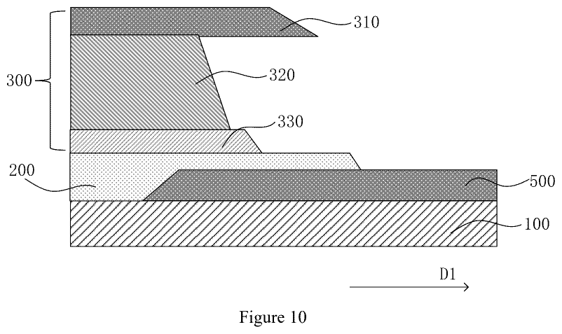

At step S40, with reference to FIG. 9, the pixel defining material layer 2001 is patterned to form a patterned photoresist 10 on the isolation structure 300 and the pixel defining material layer 2001.

First, a photoresist may be applied on the isolation structure 300 and the pixel defining material layer 2001. In this case, due to the shielding effect of the isolation structure 300, a thickness of the photoresist on the pixel defining material layer 2001 becomes thinner as the photoresist approaches the orthographic projection of the isolation structure 300 on the substrate 100.

Then, the photoresist is exposed and developed to be patterned. The patterned photoresist has a plurality of photoresist openings.

At step S50, with reference to FIG. 10 and FIG. 1, the pixel defining material layer 2001 is etched based on the patterned photoresist 10 to form a pixel defining layer 200, where the pixel defining layer 200 has a plurality of pixel openings 2001, an orthographic projection of a pixel opening 2001 on the substrate 100 is located within the orthographic projection of the isolation opening 3001 on the substrate 100, the orthographic projection of the pixel opening 2001 on the substrate 100 includes at least one first target edge 200a and at least one first non-target edge 200b, a distance between the first target edge 200a and the second target edge 300a is defined as a second distance MVP2, a distance between the first non-target edge 200b and the second non-target edge 300b is defined as a first distance MVP1, and the first distance MVP1 is smaller than the second distance MVP2.

The patterned photoresist 10 may be removed after the pixel defining layer 200 is formed.

The size and position, etc., of the plurality of pixel openings 2001 are defined by the plurality of photoresist openings.

The smaller first distance MVP1 between the orthographic projection of the pixel opening 2001 on the substrate 100 and the second non-target edge 300b can effectively increase the area of the pixel opening 2001.

Moreover, due to the larger second distance MVP2 between the first target edge 200a and the second target edge 300a, the photoresist around a photoresist opening has a relatively thick and uniform thickness on a side close to the second target edge 300a. Therefore, when the pixel defining material layer 2001 is etched based on the patterned photoresist, this part of the photoresist may not be etched away or may be etched away less. As a result, the pixel defining material layer 2001 around the pixel opening 2001 is not damaged or is less damaged on the side close to the second target edge 300a, which enables the pixel defining layer 200 around the pixel opening 2001 to have a relatively flat upper surface on the side close to a target.

At step S60, with reference to FIG. 2 and FIG. 3, a plurality of light-emitting structures 400 are formed within the plurality of pixel openings 2001 and the plurality of isolation openings 3001, where the plurality of light-emitting structures 400 includes a plurality of light-emitting units 410 and a plurality of first electrodes 420, an end of a first electrode 420 corresponding to the second target edge 300a being connected to the isolation structure 300.

Since the pixel defining layer 200 around a pixel opening 2001 has a relatively flat upper surface on the side close to the second target edge, the end of the first electrode 420 close to the second target edge is formed on the relatively flat upper surface of the pixel defining layer 200, making it less prone to disconnection. As a result, the end of the first electrode 420 corresponding to the second target edge 300a may be effectively and reliably connected to the isolation structure 300.

In this embodiment, the orthographic projection of the isolation opening 3001 on the substrate 100 includes the at least one second target edge 300a and the at least one second non-target edge 300b. Within the isolation opening 3001, the end of the first electrode 420 corresponding to the second target edge 300a is connected to the isolation structure 300, and the distance between the first target edge 200a of the pixel opening 2001 and the second target edge 300a is defined as a larger second distance MVP2. Therefore, in this case, etching damage to the upper surface of the pixel defining layer 200 close to the second target edge 300a can be effectively prevented or reduced. That is, in this case, the upper surface of the pixel defining layer 200 close to the second target edge 300a is relatively flat, and a portion of the first electrode 420 close to the second target edge 300a will not be disconnected and can be effectively connected to the isolation structure 300.

Moreover, the distance between the first non-target edge 200b of the pixel opening 2001 and the second non-target edge 300b is defined as the first distance MVP1. The first distance MVP1 is smaller than the second distance MVP2, and the area of the pixel opening 2001 can be effectively increased at the same pixel density, improving the aperture ratio, and thus improving the product lifespan.

In one embodiment, step S60 includes:
step S61, forming the plurality of light-emitting structures 400 of different colors within different pixel openings 2001 and isolation openings 3001.

In the plurality of light-emitting structures 400 of different colors, the plurality of light-emitting units 410 are made of different materials, thereby emitting light of different colors.

The plurality of light-emitting structures 400 of different colors may be sequentially formed. After the light-emitting structure 400 of one color is formed, the light-emitting structure 400 of another color is formed.

In one embodiment, step S61 includes:
step S611, forming a plurality of first-color light-emitting structures 400 within a part of the pixel openings 2001 and isolation openings 3001.

A first-color light-emitting material layer may be first evaporated over an entire surface, followed by evaporation of a first electrode material layer over the entire surface. The evaporated light-emitting material layer and first electrode material layer are separated by the isolation structure 300 at the position of the isolation opening 3001. Then, an encapsulation material layer is deposited over the entire surface by a chemical vapor deposition process. Thereafter, a photoresist mask is formed by a photolithography process. Subsequently, the encapsulation material layer is dry-etched based on the photoresist mask to form a first encapsulation layer within the isolation openings 3001 corresponding to the first color. Thereafter, the first electrode material layer and the light-emitting material layer are wet-etched based on the photoresist mask, to forming first electrodes 420 and first-color light-emitting units 410 within the isolation openings 3001 corresponding to the first color.

At step S612, a plurality of second-color light-emitting structures 400 are formed within another part of the pixel openings 2001 and isolation openings 3001 after forming the plurality of first-color light-emitting structures 400.

A second-color light-emitting material layer may be first evaporated over an entire surface, followed by evaporation of a first electrode material layer over the entire surface. The evaporated light-emitting material layer and first electrode material layer are separated by the isolation structure 300 at the position of the isolation opening 3001. Then, an encapsulation material layer is deposited over the entire surface by a chemical vapor deposition process. Thereafter, a photoresist mask is formed by a photolithography process. Subsequently, the encapsulation material layer is dry-etched based on the photoresist mask to form a first encapsulation layer within the isolation openings 3001 corresponding to the second color. Thereafter, the first electrode material layer and the light-emitting material layer are wet-etched based on the photoresist mask, to forming first electrodes 420 and second-color light-emitting units 410 within the isolation openings 3001 corresponding to the second color.

The second distance MVP2 corresponding to the first-color light-emitting structures 400 is greater than the second distance MVP2 corresponding to the second-color light-emitting structures 400. Therefore, the upper surface of the pixel defining layer 200 around the pixel opening 2001 corresponding to each first-color light-emitting structure 400 is flatter on the side close to the second target edge 300a. As a result, the light-emitting unit 410, the first electrode 420, and the first encapsulation layer of the first-color light-emitting structure 400 have uniform thicknesses and are less likely to be etched through during formation of the plurality of second-color light-emitting structures 400. In this case, the failure of the first-color light-emitting structures 400 can be prevented.

In one embodiment, step S61 further includes:
step S613, forming a plurality of third-color light-emitting structures 400 within yet another part of the pixel openings 2001 and isolation openings 3001 after forming the plurality of second-color light-emitting structures 400.

A third-color light-emitting material layer may be first evaporated over an entire surface, followed by evaporation of a first electrode material layer over the entire surface. The evaporated light-emitting material layer and first electrode material layer are separated by the isolation structure 300 at the position of the isolation opening 3001. Then, an encapsulation material layer is deposited over the entire surface by a chemical vapor deposition process. Thereafter, a photoresist mask is formed by a photolithography process. Subsequently, the encapsulation material layer is dry-etched based on the photoresist mask to form a first encapsulation layer within the isolation openings 3001 corresponding to the third color. Thereafter, the first electrode material layer and the light-emitting material layer are wet-etched based on the photoresist mask, to forming first electrodes 420 and third-color light-emitting units 410 within the isolation openings 3001 corresponding to the third color.

As an example, the second distance MVP2 corresponding to the second-color light-emitting structures 400 is greater than the second distance MVP2 corresponding to the third-color light-emitting structures 400.

In this case, it is possible to prevent the color failure of the second-color light-emitting structures 400, and enable the third-color light-emitting structures 400 to have a larger pixel opening 2001.

As an example, the second distance MVP2 corresponding to the second-color light-emitting structures 400 may also be equal to the second distance MVP2 corresponding to the third-color light-emitting structures 400.

In this case, a low failure rate of the first-color light-emitting structures 400 can be ensured. Moreover, the second distances MVP2 corresponding to the second-color light-emitting structures 400 and the third-color light-emitting structures 400 may both be set to be smaller, thereby allowing both to have larger pixel openings 2001.

In one embodiment, the plurality of first-color light-emitting structures 400 have a shorter lifespan than the plurality of second-color light-emitting structures 400 and a shorter lifespan than the plurality of third-color light-emitting structures 400. That is, the first-color light-emitting structure 400 has the shortest lifespan in the light-emitting structures 400 of the three colors.

In this embodiment, the second distance MVP2 corresponding to the light-emitting structure 400 having the shortest lifespan is set to be the largest. As described above, the larger second distance MVP2 results in the flatter upper surface of the pixel defining layer 200 close to the pixel opening 2001, the smoother first electrode 420, and thus the lower overlap impedance between the first electrode 420 and the isolation structure 300, thereby increasing the lifespan of the light-emitting structure 400.

In one embodiment, the first distances MVP1 corresponding to the light-emitting structures 400 of different colors are the same.

The first distance MVP1 corresponding to each of the plurality of light-emitting structures 400 of different colors may be set as a minimum threshold distance allowed between the orthographic projection of the pixel opening 2001 on the substrate 100 and the orthographic projection of the isolation opening 3001 on the substrate 100, and the area of the pixel opening 2001 corresponding to the light-emitting structure 400 of each color can be effectively increased. The minimum threshold distance may be set based on actual requirements.

In one embodiment, the display panel further includes a plurality of second electrodes 500. The plurality of second electrodes 500 are located on the substrate 100, and the pixel defining layer 200 is located on a side of a second electrode 500 away from the substrate 100. The pixel opening 2001 exposes at least part of the second electrode 500, and the light-emitting unit 410 of the light-emitting structure 400 can be connected to the second electrode 500.

The second electrode 500, the light-emitting unit 410, and the first electrode 420 may form a light-emitting device. It is possible to configure the second electrode 500 as an anode and the first electrode 420 as a cathode. It is also possible to configure the second electrode 500 as a cathode and the first electrode 420 as an anode.

The first distance MVP1 ranges from 0.6 μm to 2 μm, and specifically may be 0.6 μm, 0.8 μm, 1.5 μm, 1.8 μm, 2 μm. In this case, on the one hand, the smaller first distance MVP1 allows the area of the pixel opening 2001 to be increased; on the other hand, since the first distance MVP1 is greater than zero, a sufficient distance may be maintained between the second electrode 500 and the isolation structure 300, thereby preventing a short circuit between the second electrode 500 and the first electrodes 420.

It should be understood that although the steps in the flowcharts in drawings are displayed in succession as indicated by arrows, these steps are not necessarily performed in succession in the order indicated by the arrows. Unless explicitly described herein, the execution of these steps is not limited to a strict order, instead, the steps may be performed in another order. In addition, at least a part of steps in the drawings may include a plurality of steps or stages. These steps or stages are not necessarily performed at the same time, but may be performed at different moments. These steps or stages are not necessarily performed in succession, but may be performed in turn or alternately with other steps or at least a part of steps or stages in other steps. Template phrases in the method embodiments may be directly copied.

In one embodiment, with reference to FIG. 1 to FIG. 3, another display panel is provided. The display panel includes a substrate 100, a pixel defining layer 200, an isolation structure 300, and a plurality of light-emitting structures 400.

The substrate 100 may include a base substrate and a circuit layer (not shown) formed on the base substrate, etc. The base substrate may be a rigid base substrate or a flexible base substrate. The circuit layer may include a plurality of wiring layers and dielectric layers that isolate the wiring layers, etc., and a pixel circuit, etc. may be formed in the circuit layer.

The pixel defining layer 200 is located on the substrate 100. The pixel defining layer 200 has a plurality of pixel openings 2001. Specifically, with reference to FIG. 4, the display panel may include an active area AA and a non-active area. The plurality of pixel openings 2001 may be located in the active area AA.

A larger pixel opening 2001 provides a greater facing area between a cathode and an anode of a light-emitting device, resulting in a larger effective light-emitting area and a longer lifespan.

An orthographic projection of a pixel opening 2001 on the substrate includes at least one first target edge 200a.

The pixel defining layer 200 may be of a stacked structure. The plurality of pixel openings 2001 may extend through the stacked structure. Of course, the pixel defining layer 200 may also be of a single-layer structure, which is not limited herein. The pixel defining layer 200 may be made of a material, including, but is not limited to, silicon oxide, silicon nitride, aluminum oxide, zirconium oxide, or hafnium oxide, etc.

The isolation structure 300 is located on a side of the pixel defining layer 200 away from the substrate 100. The isolation structure 300 has a barrier effect during evaporation of the light-emitting structure 400.

The isolation structure 300 is made of a conductive material, thereby enabling electrical connection.

The isolation structure 300 has a plurality of isolation openings 3001. The plurality of isolation openings 3001 are in communication with the plurality of pixel openings 2001, thereby allowing the formation of the light-emitting structure 400, etc.

An orthographic projection of an isolation opening 3001 on the substrate 100 includes at least one second target edge 300a. The at least one second target edge 300a is arranged corresponding to the at least one first target edge 200a. Specifically, the “corresponding” in “the at least one second target edge 300a is arranged corresponding to the at least one first target edge 200a” means that the at least one second target edge 300a and the at least one first target edge 200a are both located on the same side of the orthographic projection of the center of the light-emitting structure 400 on the substrate 100.

One or more second target edges 300a may be provided, and one or more second non-target edges 300b may be provided, which are not limited herein.

The orthographic projection of the pixel opening 2001 on the substrate 100 is located within the orthographic projection of the isolation opening 3001 on the substrate 100. That is, the orthographic projection of the pixel opening 2001 on the substrate 100 is smaller than the orthographic projection of the isolation opening 3001 on the substrate 100.

Moreover, a distance between the first target edge 200a and the second target edge 300a is defined as a second distance MVP2.

The plurality of light-emitting structures 400 are located within the plurality of pixel openings 2001 and the plurality of isolation openings 3001. The plurality of light-emitting structures 400 includes a plurality of light-emitting units 410 and a plurality of first electrodes 420.

A light-emitting unit 410 may include a plurality of organic layers. A first electrode 420 may be a cathode or an anode. As an example, the first electrode 420 is a cathode, and the first electrodes 420 of the light-emitting structures 400 may be electrically connected to each other by connecting to the isolation structure 300.

Within the isolation opening 3001, an end of the first electrode 420 corresponding to the second target edge 300a is connected to the isolation structure 300.

The display panel includes the plurality of light-emitting structures 400 of different colors. In the plurality of light-emitting structures 400 of different colors, the second distance MVP2 corresponding to the light-emitting structure 400 of at least one color is greater than the second distances MVP2 corresponding to the light-emitting structures 400 of other colors.

It should be noted that, in the present embodiment, in the orthographic projection of each isolation opening 3001 on the substrate 100, all or part of the edges may serve as the second target edges 300a, which is not limited herein.

During preparation of the display panel, after the isolation structure 300 is formed, the plurality of light-emitting structures 400 of different colors may be sequentially formed. After the light-emitting structure 400 of one color is formed, the light-emitting structure 400 of another color is formed.

Moreover, during formation of the light-emitting structure 400 of each color, a light-emitting material layer may be first evaporated over an entire surface, followed by evaporation of a first electrode material layer over the entire surface. The evaporated light-emitting material layer and first electrode material layer are separated by the isolation structure 300 at the position of the isolation opening 3001. Then, an encapsulation material layer is deposited over the entire surface by a chemical vapor deposition process. Thereafter, a photoresist mask is formed by a photolithography process. Subsequently, the encapsulation material layer, the first electrode material layer, and the light-emitting material layer are etched based on the photoresist mask, to form a first encapsulation layer, a first electrode 420, and a light-emitting unit 410 within the isolation opening 3001 corresponding to a target color.

A dry etching method is typically used for the encapsulation material layer, and over-etching is usually required to completely etch the encapsulation material layer outside a region corresponding to the target color. Therefore, during etching of the encapsulation material layer for a post-deposited color, it is often necessary to etch into the first encapsulation layer already formed within the isolation opening 3001 for a pre-deposited color. In this case, when the second distance MVP2 corresponding to the pre-deposited color is not sufficiently large, the flatness of the upper surface of the pixel defining layer 200 corresponding to the second distance MVP2 may be insufficient. Consequently, although the light-emitting unit 410, the first electrode 420, and the first encapsulation layer for the pre-deposited color on the pixel defining layer 200 are continuous, there may still be uneven film thicknesses with thinner regions. During etching of the encapsulation material layer for the post-deposited color, the first encapsulation layer, the first electrode 420, and the light-emitting unit 410 within the isolation opening 3001 for the pre-deposited color may be etched through, and the pixel defining layer 200 beneath the light-emitting unit 410 may be damaged. This may cause metal to precipitate on the second electrode 500 beneath the pixel defining layer 200, leading to a short circuit between the second electrode and the first electrode 420, and thus leading to failure of a light-emitting device for the pre-deposited color.

Based on this, the second distance MVP2 corresponding to the light-emitting structure 400 of at least the first-prepared color may be set to be greater than the second distances MVP2 corresponding to the light-emitting structures 400 of other colors, thereby reducing the failure rate of light-emitting devices.

Specifically, as an example, the second distances MVP2 corresponding to the plurality of light-emitting structures 400 of different colors may be set to be completely different.

The earlier the preparation sequence of a color, the more times the first encapsulation layer already formed within the isolation opening 3001 therefor is etched. Therefore, it can be set that the color with an earlier preparation sequence corresponds to a larger second distance MVP2, and the color with a later preparation sequence corresponds to a smaller second distance MVP2, and the second distances MVP2 corresponding to the plurality of light-emitting structures 400 of different colors are completely different.

In this way, it is possible to prevent the failure of the pre-deposited color, and provide a larger pixel opening 2001 for the post-deposited color.

In this embodiment, the second distance corresponding to the light-emitting structure of at least one color is set to be greater than those corresponding to the light-emitting structures of other colors. In this way, during preparation of the display panel, the light-emitting structure prepared earlier corresponds to a greater second distance, preventing damage to the light-emitting structure of the pre-deposited color during etching of the subsequently prepared light-emitting structure, and thus reducing the failure rate of light-emitting devices.

In one embodiment, the plurality of light-emitting structures 400 of different colors include a plurality of first-color light-emitting structures, a plurality of second-color light-emitting structures, and a plurality of third-color light-emitting structures.

During preparation of the display panel, the plurality of first-color light-emitting structures, the plurality of second-color light-emitting structures, and the plurality of third-color light-emitting structures may be sequentially prepared.

The second distance MVP2 corresponding to a first-color light-emitting structure, the second distance MVP2 corresponding to a second-color light-emitting structure, and the second distance MVP2 corresponding to a third-color light-emitting structure decrease in sequence.

In one embodiment, the lifespan of the first-color light-emitting structure, the lifespan of the second-color light-emitting structure, and the lifespan of the third-color light-emitting structure increase in sequence.

In this case, during preparation of the display panel, the light-emitting structure having a shorter lifespan is prepared earlier, and the light-emitting structure having a shorter lifespan corresponds to a larger second distance MVP2. This not only prevents failure of the light-emitting structure having a short lifespan, but also increases the overlap area between its first electrode and the isolation structure, thereby improving the lifespan thereof.

In one embodiment, the plurality of light-emitting structures 400 of different colors include a plurality of first-color light-emitting structures, a plurality of second-color light-emitting structures, and a plurality of third-color light-emitting structures, where the second distance MVP2 corresponding to a first-color light-emitting structure is greater than the second distance MVP2 corresponding to a second-color light-emitting structure, and the second distance MVP2 corresponding to a third-color light-emitting structure is equal to the second distance MVP2 corresponding to the second-color light-emitting structure.

In this case, a low failure rate of the first-color light-emitting structures 400 can be ensured. Moreover, the second distances MVP2 corresponding to the second-color light-emitting structures 400 and the third-color light-emitting structures 400 may both be set to be smaller, thereby allowing both to have larger pixel openings 2001.

The embodiments of the present application further provide a display device (not shown). The display device includes a display panel of the above embodiments. As an example, it is possible to configure a length direction of the display device as the first direction and a width direction of the display device as the second direction. As another example, it is also possible to configure the length direction of the display device as the second direction and the width direction of the display device as the first direction.

It should be understood that the display device in the embodiments of the present application may be any product or component having a display function, such as an OLED display device, a QLED display device, an electronic paper, a mobile phone, a tablet computer, a TV, a display, a laptop computer, a digital photo frame, a navigator, a wearable device, and an Internet of Things device, which is not limited in the embodiments disclosed in the present application.

In the description of this description, the description with reference to the terms such as “some embodiments”, “other embodiments”, and “ideal embodiments” means that specific features, structures, materials, or characteristics described with respect to the embodiments or examples are included in at least one embodiment or example of the present application. In this description, the schematic descriptions of the above terms do not necessarily refer to the same embodiments or examples.

The embodiments may be randomly combined. To make the description concise, not all possible combinations of the above embodiments are described. However, the combinations of these features shall be considered as falling within the scope recorded in this specification provided that no conflict exists.

The above embodiments merely represent several implementations of the present application, giving specifics and details thereof, but should not be understood as limiting the scope of the disclosure thereby. It should be noted that several alterations and improvements without departing from the spirit of the present application and these would all fall within the scope of protection of the present application. Therefore, the scope of protection of the present patent application shall be in accordance with the appended claims.

1. A display panel, comprising:
a substrate;
a pixel defining layer located on the substrate and having a plurality of pixel openings, an orthographic projection of a pixel opening on the substrate comprising at least one first target edge and at least one first non-target edge;
an isolation structure located on a side of the pixel defining layer away from the substrate and having a plurality of isolation openings in communication with the plurality of pixel openings, an orthographic projection of an isolation opening on the substrate comprising at least one second target edge and at least one second non-target edge, the at least one second target edge being arranged corresponding to the at least one first target edge, the at least one second non-target edge being arranged corresponding to the at least one first non-target edge, the orthographic projection of the pixel opening on the substrate being located within the orthographic projection of the isolation opening on the substrate, a distance between the first non-target edge and the second non-target edge being defined as a first distance, a distance between the first target edge and the second target edge being defined as a second distance, and the first distance being smaller than the second distance; and
a plurality of light-emitting structures located within the plurality of pixel openings and the plurality of isolation openings and comprising a plurality of light-emitting units and a plurality of first electrodes, within the isolation opening, an end of a first electrode corresponding to the second target edge being connected to the isolation structure.

2. The display panel according to claim 1, wherein two oppositely arranged edges of the orthographic projection of the isolation opening on the substrate are the second target edges; or one of edges of the orthographic projection of the isolation opening on the substrate is the second target edge.

3. The display panel according to claim 1, wherein the display panel comprises the plurality of light-emitting structures of different colors, the first distances corresponding to the light-emitting structures of different colors being the same; and
the display panel further comprises a plurality of second electrodes, the plurality of second electrodes being located on the substrate, the pixel defining layer being located on a side of a second electrode away from the substrate, the pixel opening exposing at least part of the second electrode, and the first distance ranging from 0.6 μm to 2 μm.

4. The display panel according to claim 1, wherein the display panel comprises the plurality of light-emitting structures of different colors, in the plurality of light-emitting structures of different colors, the second distance corresponding to the light-emitting structure of at least one color being greater than the second distances corresponding to the light-emitting structures of other colors.

5. The display panel according to claim 4, wherein the plurality of light-emitting structures of different colors comprise a plurality of first-color light-emitting structures, a plurality of second-color light-emitting structures, and a plurality of third-color light-emitting structures, wherein the second distance corresponding to a first-color light-emitting structure is greater than the second distance corresponding to a second-color light-emitting structure, and the second distance corresponding to a third-color light-emitting structure is equal to the second distance corresponding to the second-color light-emitting structure.

6. The display panel according to claim 4, wherein in the plurality of light-emitting structures of different colors, the light-emitting structure having a shortest lifespan corresponds to a largest second distance;
the light-emitting structure having a shorter lifespan corresponds to a larger second distance;
the plurality of light-emitting structures of different colors comprise a plurality of first-color light-emitting structures, a plurality of second-color light-emitting structures, and a plurality of third-color light-emitting structures, the second distance corresponding to a first-color light-emitting structure being greater than the second distance corresponding to a second-color light-emitting structure, and the second distance corresponding to the second-color light-emitting structure being greater than the second distance corresponding to a third-color light-emitting structure, wherein the first-color light-emitting structure has a shorter lifespan than the second-color light-emitting structure, and the second-color light-emitting structure has shorter lifespan than the third-color light-emitting structure; and
the first-color light-emitting structure is configured to emit blue light, the second-color light-emitting structure is configured to emit green light, and the third-color light-emitting structure is configured to emit red light.

7. The display panel according to claim 1, wherein
the display panel comprises the plurality of light-emitting structures of different colors, wherein in the plurality of light-emitting structures of different colors, the orthographic projection of the isolation opening corresponding to a light-emitting structure having a shortest lifespan on the substrate comprises at least one first edge and at least one second edge, the at least one first edge has a greater length than the at least one second edge, an extending direction of the at least one first edge is a first direction, and an extending direction of the at least one second edge is a second direction, the second direction intersecting the first direction;
the second target edge corresponding to the light-emitting structure having the shortest lifespan is the first edge;
the second target edges corresponding to the other light-emitting structures are parallel to the first edge; and
the second target edges corresponding to the light-emitting structures of different colors are all located on the same side of the light-emitting structures.

8. The display panel according to claim 1, wherein the orthographic projection of the isolation opening on the substrate comprises at least one second straight edge and at least one second curved edge, wherein the second target edge is the second straight edge; and the second non-target edge is also a second straight edge; and the second curved edge is located between the second non-target edge and the second target edge, or between two adjacent second non-target edges.

9. The display panel according to claim 8, wherein
the orthographic projection of the pixel opening on the substrate comprises at least one first straight edge and at least one first curved edge, wherein the at least one first straight edge is arranged corresponding to the second straight edge, the at least one first curved edge is arranged corresponding to the at least one second curved edge, a distance between the first curved edge and the second curved edge is defined as a third distance, and the third distance has a greater value on a side close to the first target edge than on a side close to the first non-target edge.

10. The display panel according to claim 1, wherein the isolation structure comprises a first isolation portion and a second isolation portion, wherein the first isolation portion is located on a side of the second isolation portion away from the substrate, an orthographic projection of the second isolation portion on the substrate is located within an orthographic projection of the first isolation portion on the substrate, and the orthographic projection of the isolation opening on the substrate is an orthographic projection of an opening of the first isolation portion on the substrate;
the second isolation portion is made of a conductive material, and the first electrode overlap with a sidewall of the second isolation portion; and
the isolation structure further comprises a third isolation portion, wherein the third isolation portion is located between the pixel defining layer and the second isolation portion, and the orthographic projection of the second isolation portion on the substrate is located within an orthographic projection of the third isolation portion on the substrate.

11. The display panel according to claim 1, wherein the second distance ranges from 2 μm to 4 μm.

12. A display panel, comprising:
a substrate;
a pixel defining layer located on the substrate and having a plurality of pixel openings, an orthographic projection of a pixel opening on the substrate comprising at least one first target edge;
an isolation structure located on a side of the pixel defining layer away from the substrate and having a plurality of isolation openings in communication with the plurality of pixel openings, an orthographic projection of an isolation opening on the substrate comprising at least one second target edge, the at least one second target edge being arranged corresponding to the at least one first target edge, the orthographic projection of the pixel opening on the substrate being located within orthographic projection of the isolation opening on the substrate, and a distance between the first target edge and the second target edge being defined as a second distance; and
a plurality of light-emitting structures located within the plurality of pixel openings and the plurality of isolation openings and comprising a plurality of light-emitting units and a plurality of first electrodes, within the isolation opening, an end of a first electrode corresponding to the second target edge being connected to the isolation structure,
wherein the display panel comprises the plurality of light-emitting structures of different colors, in the plurality of light-emitting structures of different colors, the second distance corresponding to the light-emitting structure of at least one color being greater than the second distances corresponding to the light-emitting structures of other colors.

13. The display panel according to claim 12, wherein the second distances corresponding to the plurality of light-emitting structures of different colors are completely different.

14. The display panel according to claim 13, wherein the plurality of light-emitting structures of different colors comprise a plurality of first-color light-emitting structures, a plurality of second-color light-emitting structures, and a plurality of third-color light-emitting structures, wherein the second distance corresponding to a first-color light-emitting structure, the second distance corresponding to a second-color light-emitting structure and the second distance corresponding to a third-color light-emitting structure decrease in sequence.

15. The display panel according to claim 14, wherein lifespans of the first-color light-emitting structure, the second-color light-emitting structure, and the third-color light-emitting structure increase in sequence.

16. A method for preparing a display panel, comprising:
providing a substrate;
sequentially forming a pixel defining material layer and an isolation material layer on the substrate;
patterning the isolation material layer to form an isolation structure, wherein the isolation structure has a plurality of isolation openings, and an orthographic projection of an isolation opening on the substrate comprises at least one second target edge and at least one second non-target edge;
patterning the pixel defining material layer to form a patterned photoresist on the isolation structure and the pixel defining material layer;
etching the pixel defining material layer based on the patterned photoresist to form a pixel defining layer, wherein the pixel defining layer has a plurality of pixel openings, an orthographic projection of a pixel opening on the substrate is located within the orthographic projection of the isolation opening on the substrate, the orthographic projection of the pixel opening on the substrate comprises at least one first target edge and at least one first non-target edge, a distance between the first non-target edge and the second non-target edge is defined as a first distance, a distance between the first target edge and the second target edge is defined as a second distance, and the first distance is smaller than the second distance; and
forming a plurality of light-emitting structures within the plurality of pixel openings and the plurality of isolation openings, wherein the plurality of light-emitting structures comprise a plurality of light-emitting units and a plurality of first electrodes, an end of a first electrode corresponding to the second target edge being connected to the isolation structure.

17. The method for preparing a display panel according to claim 16, wherein forming the plurality of light-emitting structures within the plurality of pixel openings and the plurality of isolation openings comprises:
forming the plurality of light-emitting structures of different colors within different pixel openings and isolation openings.

18. The method for preparing a display panel according to claim 17, wherein forming the plurality of light-emitting structures of different colors within the different pixel openings and isolation openings comprises:
forming a plurality of first-color light-emitting structures within a part of the pixel openings and isolation openings; and
forming a plurality of second-color light-emitting structures within another part of the pixel openings and isolation openings after forming the plurality of first-color light-emitting structures,
wherein the second distance corresponding to the first-color light-emitting structures is greater than the second distance corresponding to the second-color light-emitting structures.

19. The method for preparing a display panel according to claim 18, wherein forming the plurality of light-emitting structures of different colors within the different pixel openings and isolation openings further comprises:
forming a plurality of third-color light-emitting structures within yet another part of the pixel openings and isolation openings after forming the plurality of second-color light-emitting structures,
wherein the second distance corresponding to the second-color light-emitting structures is greater than or equal to the second distance corresponding to the third-color light-emitting structures.

20. The method for preparing a display panel according to claim 19, wherein the plurality of first-color light-emitting structures have a shorter lifespan than the plurality of second-color light-emitting structures and a shorter lifespan than the plurality of third-color light-emitting structures.
